(19) United States
(12) Patent Application Publication
(10) Pub. No.: US 2015/0139261 A1
(43) Pub. Date: May 21, 2015

(54) SEMICONDUCTOR DEVICE HAVING A SEMICONDUCTOR DBR LAYER

(71) Applicant: Sanken Electric Co., Ltd., Niiza-shi (JP)

(72) Inventor: Tetsuji MATSUO, Niiza-shi (JP)

(21) Appl. No.: 14/547,182

(22) Filed: Nov. 19, 2014

(30) Foreign Application Priority Data
Nov. 21, 2013 (JP) 2013-240787

(51) Int. Cl. H01S 5/125; H01S 5/02; H01S 5/323

(52) U.S. Cl. CPC H01S 5/125; H01S 5/32341; H01S 5/021
USPC 372/50.11

(57) ABSTRACT

A semiconductor device includes a silicon substrate, alight-emitting function layer made of nitride semiconductor, and at least one multilayer film in which two to four lamination pairs are laminated, the lamination pair being a laminated body of a first semiconductor layer made of AlₓGa₁₋ₓN and a second semiconductor layer made of Al_{Y}Ga_{1-Y}N, the multilayer film being arranged between the silicon substrate and the light-emitting function layer, wherein in the lamination pair that is the closest to the light-emitting function layer in the multilayer film, an Al composition X is equal to or larger than an Al composition Y, in the other lamination pair, the Al composition X is larger than the Al composition Y.

### CROSS REFERENCE TO RELATED APPLICATIONS AND INCORPORATION BY REFERENCE

This application is based upon and claims the benefit of priority from prior Japanese Patent Application P2013-240787 filed on Nov. 21, 2013; the entire contents of which are incorporated by reference herein.

### BACKGROUND OF THE INVENTION

1. Field of the Invention

The present invention relates to a semiconductor device having a semiconductor DBR layer formed on a silicon substrate.

2. Description of the Related Art

As a semiconductor DBR layer of a distributed Bragg reflector (DBR) semiconductor laser, a structure has been employed, in which two layers having different reflective indexes from each other are laminated alternately on a semiconductor substrate. In this case, a material with a relatively small lattice mismatch ratio with respect to the semiconductor substrate has been used for each layer of the semiconductor DBR layer. For example, a semiconductor DBR layer, in which AlGaAs/GaAs layers are laminated, or a semiconductor DBR layer, in which AlGaInP-based layers are laminated, has been manufactured on a GaAs substrate.

For a semiconductor device having a GaN-based element function layer made of a nitride semiconductor, it is preferred to use an inexpensive silicon substrate. However, a lattice mismatch ratio is large between a silicon substrate and a GaN-based semiconductor layer. Therefore, measures have been taken such as arranging a buffer layer between the semiconductor substrate and the element function layer so as to restrain defects and cracks caused by lattice mismatch between the semiconductor substrate and the element function layer.

However, a buffer layer needs to have a film thickness of about 1 μm to 4 μm. Therefore, in a case where a light-emitting function layer, which uses reflection on a semiconductor DBR layer, is formed on a silicon substrate, a buffer layer with a film thickness of about 1 μm to 4 μm is formed on the silicon substrate, and the semiconductor DBR layer is formed on the buffer layer. A thickness of the semiconductor DBR layer is generally 1 μm to 10 μm. Therefore, combining the buffer layer and the semiconductor DBR layer means forming a semiconductor layer having a thickness of about 2 μm to 14 μm. When a semiconductor layer with such a large thickness is formed, growing time is increased, which causes reduction in productivity of a semiconductor device and an increase of manufacturing costs.

### SUMMARY OF THE INVENTION

An aspect of the present invention is a semiconductor device. The semiconductor device includes a silicon substrate; a light-emitting function layer made of nitride semiconductor; and at least one multilayer film in which two to four lamination pairs are laminated, the lamination pair being a laminated body of a first semiconductor layer made of AlₓGa₁₋ₓN (0≦X≦1) and a second semiconductor layer made of Al_{Y}Ga_{1-Y}N (0≦Y<1), the multilayer film being arranged between the silicon substrate and the light-emitting function layer. In the lamination pair that is the closest to the light-emitting function layer in the multilayer film, an Al composition X of the first semiconductor layer is equal to or larger than an Al composition Y of the second semiconductor layer. In the lamination pair other than the lamination pair that is the closest to the light-emitting function layer in the multilayer film, the Al composition X of the first semiconductor layer is larger than the Al composition Y of the second semiconductor layer. In the multilayer film, the Al composition X of the first semiconductor layer of the lamination pair that is the closest to the silicon substrate is the largest among those of all the first semiconductor layers and the second semiconductor layers included in the multilayer film. In the multilayer film, the Al composition X of the first semiconductor layer of the lamination pair that is the closes to the light-emitting function layer is the smallest among those of all the first semiconductor layers included in the multilayer film.

### BRIEF DESCRIPTION OF THE DRAWINGS

FIG. 1 is a schematic view showing a structure of a semiconductor device according to a first embodiment of the present invention;

FIG. 2 is a schematic view showing an example of a structure of a semiconductor DBR layer of the semiconductor device according to the first embodiment of the present invention;

FIG. 3 is a graph showing a relationship between an Al composition of an AlGaN film of the DBR structure and an average density of cracks occurred within a wafer surface;

FIG. 4 is a table showing structures of the semiconductor DBR layers in level 1 to level 5;

FIG. 5 is a graph showing average densities of cracks occurred in wafer surfaces in level 1 to level 5.

FIG. 6 is a schematic view showing an example of the structure of the semiconductor DBR layer of the semiconductor device according to the first embodiment of the present invention;

FIG. 7 is a graph showing a difference in average crack density in different structures of the first semiconductor layer of the semiconductor device according to the first embodiment of the present invention;

FIG. 8 is a schematic view showing an example of a structure of the first semiconductor layer of the semiconductor device according to the first embodiment of the present invention; and

FIG. 9 is a schematic view showing a structure of a semiconductor device according to a second embodiment of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

In the following descriptions, numerous specific details are set forth such as specific signal values, etc., to provide a thorough understanding of the present invention. However, it will be obvious to those skilled in the art that the present invention may be practiced without such specific details.

### First Embodiments

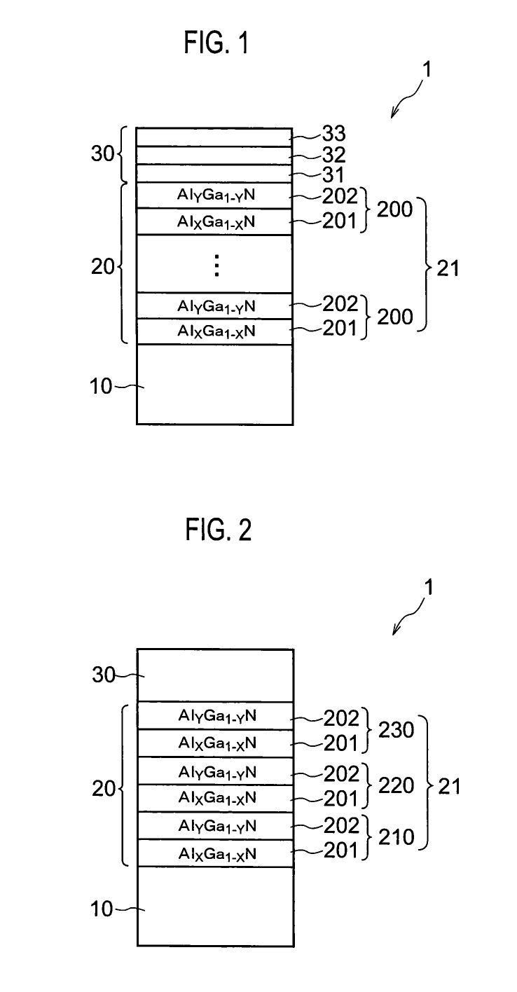

As shown in FIG. 1, a semiconductor device 1 according to a first embodiment of the present invention includes a silicon substrate 10, a light-emitting function layer 30 made of nitride semiconductor, and a semiconductor DBR layer 20 arranged between the silicon substrate 10 and the light-emitting function layer 30. The semiconductor device 1 is a DBR-type light-emitting device in which light emitted from the light-emitting function layer 30 is reflected by the semiconductor DBR layer 20. For example, as shown in FIG. 1 as an example, a double-hetero structure, in which an n-type clad layer 31, a luminescent layer 32, and a p-type clad layer 33 are laminated, may be employed for the light-emitting function layer 30. In the luminescent layer 32, an electron is injected into from the n-type clad layer 31, and a hole is injected from the p-type clad layer 33. As the injected electron and hole are recombined in the luminescent layer 32, light is generated.

As stated earlier, when a buffer layer and a semiconductor DBR layer are laminated on a silicon substrate, growing time is increased, thus causing an increase in manufacturing costs of a semiconductor device. On the contrary, in the semiconductor device 1 shown in FIG. 1, the semiconductor DBR layer 20 also functions as a buffer layer arranged on the silicon substrate 10. Therefore, it is not necessary to specially form a buffer layer, and productivity of the semiconductor device 1 is thus improved, thereby restraining an increase in manufacturing costs.

The semiconductor DBR layer 20 has a multilayer film 21 in which two to four lamination pairs 200 are laminated. The lamination pair 200 is a laminated body of a first semiconductor layer 201 made of AlₓGa_{1-X}N (0≦X≦1) and a second semiconductor layer 202 made of Al_{Y}Ga_{1-Y}N (0≦Y<1) serves as. It is possible to form the semiconductor DBR layer 20 by using, for example, a metalorganic vapor phase epitaxy (MOVPE) apparatus.

FIG. 2 shows an example where the multilayer film 21 has three lamination pairs 200. This means that the multilayer film 21 shown in FIG. 2 is made of a first lamination pair 210 that is the closest to the silicon substrate 10, a second lamination pair 220 arranged on the first lamination pair 210, and a third lamination pair 230 arranged on the second lamination pair 220. FIG. 1 and FIG. 2 show an example where the semiconductor DBR layer 20 has one multilayer film 21.

In the lamination pair 200 in the multilayer film 21, which is the closest to the light-emitting function layer 30, an Al composition X of the first semiconductor layer 201 is equal to or larger than an Al composition Y of the second semiconductor layer 202. This means that, in the example shown in FIG. 2, a relationship of X≧Y is satisfied in the third lamination pair 230.

Meanwhile, in the lamination pairs 200 in the multilayer film 21, other than the lamination pair 200 that is the closest to the light-emitting function layer 30, an Al composition X of the first semiconductor layer 201 is larger than an Al composition Y of the second semiconductor layer 202. This means that, in the example shown in FIG. 2, a relationship of X>Y is satisfied in the first lamination pair 210 and the second lamination pair 220.

Therefore, the multilayer film 21 has a structure in which the first semiconductor layer 201 and the second semiconductor layer 202 having a smaller Al composition than that of the first semiconductor layer 201 are laminated alternately. Any of the Al compositions X of the first lamination pair 210 to the third lamination pair 230 is set to be larger than any of the Al compositions Y of the first lamination pair 210 to the third lamination pair 230.

However, in the lamination pair 200 that is the closest to the light-emitting function layer 30, the Al composition X of the first semiconductor layer 201 and the Al composition Y of the second semiconductor layer 202 maybe the same. For example, in the third lamination pair 230, both of the first semiconductor layer 201 and the second semiconductor layer 202 may be a GaN film with a relationship of X=Y=0.

Also, in the multilayer film 21, the Al composition X of the first semiconductor layer 201 of the lamination pair 200 that is the closest to the silicon substrate 10 is the largest among those of all the first semiconductor layers 201 and the second semiconductor layers 202 included in the multilayer film 21. For example, the Al composition X of the first semiconductor layer 201 of the first lamination pair 210 is larger than the Al compositions X of all the semiconductor layers included in the multilayer film 21. Then, the Al composition X of the first semiconductor layer 201 of the lamination pair 200 that is the closest to the light-emitting function layer 30 in the multilayer film 21 is the smallest among those of all the first semiconductor layers 201 included in the multilayer film 21. For example, the Al composition X of the first semiconductor layer 201 in the third lamination pair 230 is smaller than the Al compositions X of the first semiconductor layers 201 of the first lamination pair 210 and the second lamination pair 220.

To be more specific, with regard to the Al compositions X of the first semiconductor layers 201, the Al compositions X in the first lamination pair 210 and the second lamination pair 220 are the same, and the Al composition X in the third lamination pair 230 is smaller than those in the first lamination pair 210 and the second lamination pair 220. Alternatively, the Al composition X in the first lamination pair 210 may be smaller than that in the second lamination pair 220, and the Al composition X in the third lamination pair 230 may be smaller than that in the second lamination pair 220.

Since the semiconductor DBR layer 20 is a reflecting layer of the light-emitting function layer 30, a film thickness of each layer in the semiconductor DBR layer 20 depends of a wavelength of light generated in the luminescent layer 32. To be specific, in order to reflect light effectively, a film thickness of each layer in the semiconductor DBR layer 20 is set to be λ/(4×n), where λ is a wavelength of light and n is a reflective index of the film.

In reality, film thickness is corrected within ±20% for optimization so that an optical output of the semiconductor device 1 increases. In other words, a film thickness d of each layer in the semiconductor DBR layer 20 is set so as to satisfy a relationship of formula (1).

d=(α×λ)/(4×n) and 0.8≦α≦1.2 (1)

In formula (1), a coefficient a represents film thickness correction within ±20%. When a reflective index of the first semiconductor layer 201 is n₁, a film thickness d₁ of the first semiconductor layer 201 is (α×λ)/(4×n₁). When a reflective index of the second semiconductor layer 202 is n₂, a film thickness d₂ of the second semiconductor layer 202 is (α×λ)/(4×n₂).

For example, in a case where a blue light-emitting device with an emission wavelength of 460 nm is fabricated, the film thickness d of each layer is about 50 nm. In other words, the film thicknesses of the first semiconductor layer 201 and the second semiconductor layer 202 are set to about 50 nm. In a case where a green light-emitting device with an emission wavelength of 520 nm is fabricated, the film thickness d of each layer is about 56 nm.

However, cracks happen when a laminated body, in which two kinds of films that are an Al_{0.5}Ga_{0.5}N film with a film thickness of 50 nm and a GaN film with a thickness 50 nm are laminated alternately on a 6-inch silicon wafer, is repeated about 30 times to fabricate a DBR structure. This is because an average Al composition of the whole DBR structure becomes too large. As an Al composition becomes large, a difference in lattice constant between silicon and nitride semiconductor becomes larger, and further, defects of an epitaxial layer are increased. Therefore, cracks are more likely to happen. The “average Al composition” means a value of an average Al composition of all layers.

Even if the Al composition of the AlGaN film is changed in the above-mentioned DBR structure, cracks occur in all Al compositions. In other words, when the Al composition is increased to be larger than 0.5, cracks happen due to a difference in lattice constant and degradation of crystal quality as described above.

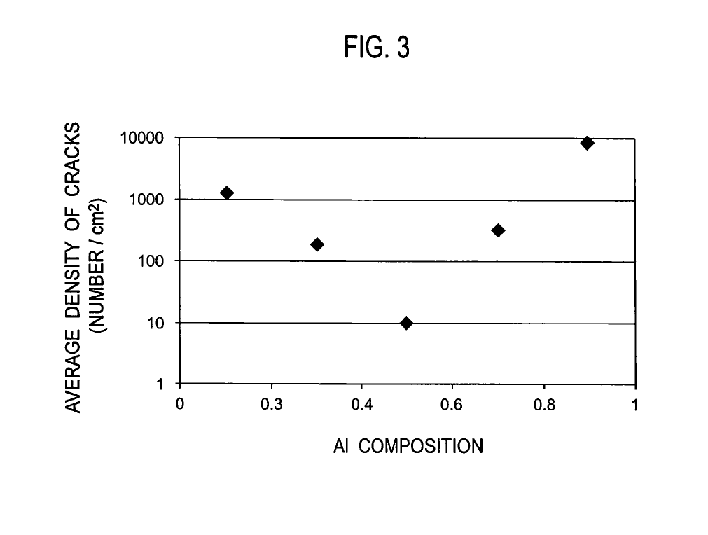

On the other hand, in the laminated body of the AlGaN film and the GaN film, cracks occur in a case where the Al composition of the AlGaN film is decreased to be smaller than 0.5. This is because, unless a difference in Al composition between the films within the DBR structure is a certain level or larger, it is not possible to obtain an effect of suppressing occurrence of cracks, which is obtained by an effect of mitigating strain between a silicon substrate and an epitaxial layer, the strain being caused by a difference in lattice constant between the silicon substrate and the GaN-based epitaxial layer. In order to obtain the effect of suppressing occurrence of cracks, a difference in Al composition at a heterointerface between films within the DBR structure (for example, between the AlGaN film and the GaN film) needs to be about 0.5 or larger. Herein below, the effect of suppressing occurrence of cracks caused by a difference in Al composition at a heterointerface in the DBR structure will be referred to as a “buffer layer effect”. FIG. 3 shows a relationship between an Al composition of the AlGaN film of the DBR structure, and an average density of cracks that occur within a wafer surface.

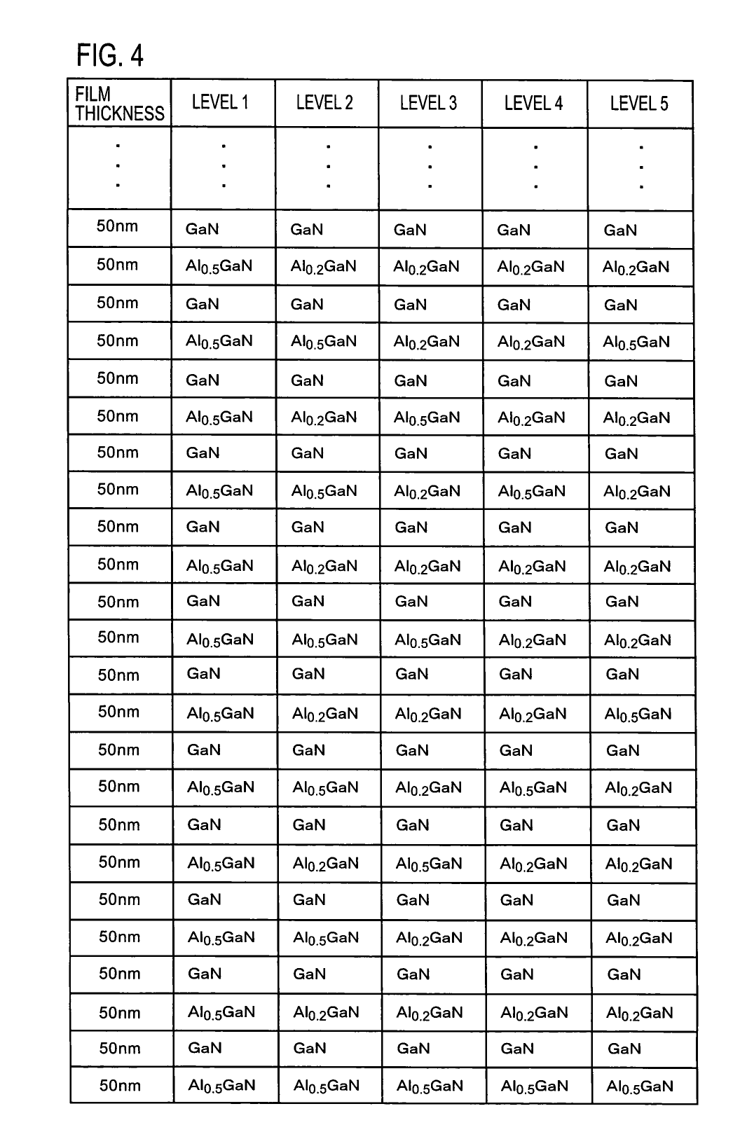

In view of the above-mentioned knowledge, the inventors carried out study stated below in order to find out a structure of the semiconductor DBR layer 20 in which occurrence of cracks is suppressed. Occurrence of cracks was investigated for level 1 to level 5 shown in FIG. 4, in which the number of the lamination pairs 200 of the multilayer film 21 included in the semiconductor DBR layer 20, and Al composition of each of the layers are changed. The first semiconductor layer 201 is an AlGaN film with a film thickness of 50 nm, and the second semiconductor layer 202 is a GaN film with a film thickness of 50 nm.

As previously described, in order to obtain the buffer layer effect that suppresses occurrence of cracks by a difference in Al composition between the first semiconductor layer 201 and the second semiconductor layer 202, a difference in Al composition needs to be 0.5 or larger. Therefore, level 1 to level 5 are set so that the multiplayer film 21 includes one lamination pair in which a difference in Al composition is 0.5.

In level 1, a laminated body, in which the first semiconductor layer 201 and the second semiconductor layer 202 are laminated one by one, serves as the lamination pair 200. Here, the first semiconductor layer 201 is an Al_{0.5}Ga_{0.5}N film with an Al composition X of 0.5, and the second semiconductor layer 202 is a GaN film. In short, the semiconductor DBR layer 20 has a structure in which the Al_{0.5}Ga_{0.5}N film and the GaN film are laminated alternately.

Level 2 is a structure in which a lamination pair 200, which is made of the first semiconductor layer 201 that is an Al_{0.2}Ga_{0.8}N film with an Al composition X of 0.2, and a second semiconductor layer 202 that is a GaN film, is laminated on the lamination pair 200, which is made of the first semiconductor layer 201 that is an Al_{0.5}Ga_{0.5}N film with an Al composition X of 0.5, and the second semiconductor layer 202 that is a GaN film. In short, the multilayer film 21 has two lamination pairs 200.

Level 3 is a structure in which two lamination pairs 200, each of which is made of the first semiconductor layer 201 that is an Al_{0.2}Ga_{0.8}N film with an Al composition X of 0.2, and the second semiconductor layer 202 that is a GaN film, are laminated on the lamination pair 200, which is made of the first semiconductor layer 201 that is an Al_{0.5}Ga_{0.5}N film with an Al composition X of 0.5, and the second semiconductor layer 202 that is a GaN film. In short, the multilayer film 21 has three lamination pairs 200.

Level 4 is a structure in which three lamination pairs 200, each of which is made of the first semiconductor layer 201 that is an Al_{0.2}Ga_{0.8}N film with an Al composition X of 0.2, and the second semiconductor layer 202 that is a GaN film, are laminated on the lamination pair 200 made of the first semiconductor layer 201 that is an Al_{0.5}Ga_{0.5}N film with an Al composition X of 0.5, and a second semiconductor layer 202 that is a GaN film. In short, the multilayer film 21 has four lamination pairs 200.

Level 5 is a structure in which four lamination pairs 200, each of which is made of the first semiconductor layer 201 that is an Al_{0.2}Ga_{0.8}N film with an Al composition X of 0.2, and the second semiconductor layer 202 that is a GaN film, are laminated on the lamination pair 200 made of the first semiconductor layer 201 that is an Al_{0.5}Ga_{0.5}N film with an Al composition X of 0.5, and the second semiconductor layer 202 that is a GaN film. In short, the multilayer film 21 has five lamination pairs 200.

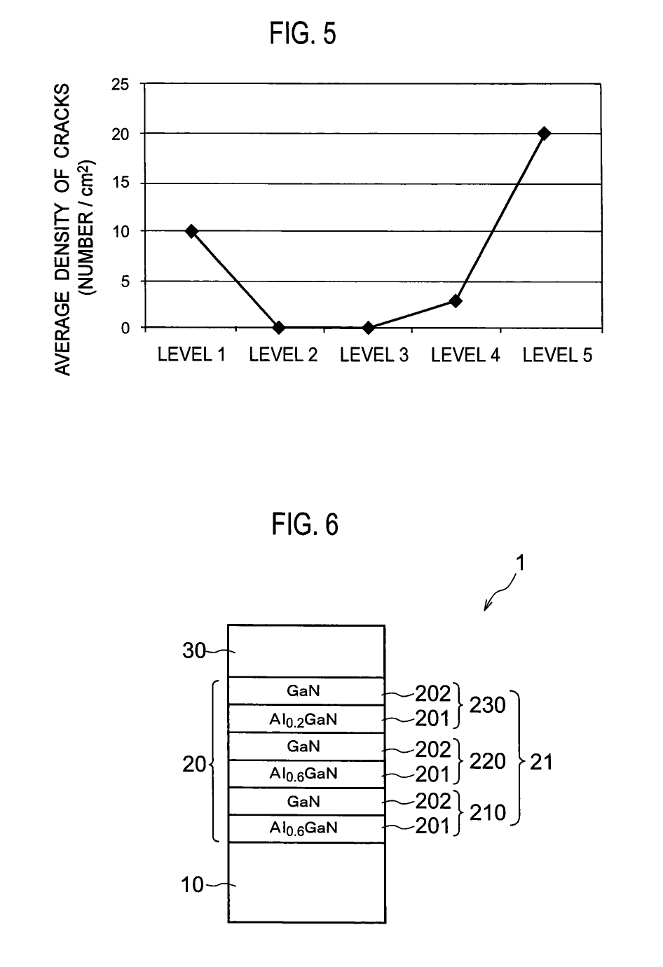

FIG. 5 shows average densities of cracks within wafer surfaces of level 1 to level 5. As shown in FIG. 5, less cracks occur in the case of level 2 to level 4. The inventors thus discovered that occurrence of cracks is suppressed in a structure where one to three lamination pairs 200, each of which is made of an Al_{0.2}Ga_{0.8}N film and a GaN film, are laminated on the lamination pair 200 made of an Al_{0.5}Ga_{0.5}N film and a GaN film. In short, in a case where the multilayer film 21 has two to four lamination pairs 200, less cracks are generated.

Among all the first semiconductor layers 201 and semiconductor layers 202 included in the multilayer film 21, the lowermost first semiconductor layer 201, which is the closest to the silicon substrate 10, has the largest Al composition. In all the lamination pairs 200 included in the multilayer film 21, the Al compositions X of the first semiconductor layers 201 are larger than Al compositions Y of the second semiconductor layers 202. Further, in the multilayer film 21, the Al composition X of the first semiconductor layer 201 is the smallest in the uppermost lamination pair 200, which is the closest to the light-emitting function layer 30, and, the Al composition X of the first semiconductor layer 201 of the uppermost lamination pair 200 does not become larger than the Al compositions X of the rest of the first semiconductor layers 201 included in the multilayer film 21. In short, in the multilayer film 21, the Al composition X becomes gradually smaller from the first semiconductor layer 201 that is the closest to the silicon substrate 10 towards the first semiconductor layer 201 that is the closest to the light-emitting function layer 30.

In order to obtain the buffer layer effect, a difference in Al composition needs to be 0.5 or larger. However, as a result of in-depth study by the inventors, it was found that, as described above, in the structure in which a plurality of lamination pairs made by laminating an AlGaN film and a GaN film are laminated, not all the lamination pairs need to have a difference in Al composition of 0.5 or larger. This indicates that the buffer layer effect, which is obtained by a lamination pair having a difference in Al composition of 0.5 or larger, reaches to a certain film thickness beyond the lamination pair. As shown in FIG. 4 and FIG. 5, the buffer layer effect is obtained as long as there is a lamination pair having a difference in Al composition of 0.5 or larger in two to four pairs.

However, as in level 5, the buffer effect is not obtained in a case where there is one lamination pair with a difference in Al composition of 0.5 or larger in five pairs. Also, in level 1, since all the lamination pairs have a difference in Al composition of 0.5 or larger, cracks occur because an average Al composition of the entire DBR structure is too large.

As shown in FIG. 5, when there are two or three lamination pairs 200, occurrence of cracks are suppressed well. As a result of the in-depth study, it was found that the case with the three lamination pairs 200 is the optimum.

When converted into a film thickness, it is only necessary that there is a lamination pair with a difference in Al composition of 0.5 or larger within a film thickness of 200 nm to 400 nm in order to obtain the buffer layer effect. However, this converted value of a film thickness is true only when a film thickness of each layer corresponding to a wavelength of light emitted by the luminescent layer 32 so as to satisfy the formula (1) is about 50 nm. In short, a value of a film thickness, by which the buffer layer effect is obtained, changes according to a wavelength of light emitted by the luminescent layer 32.

Among the first semiconductor layers 201 included in the multilayer film 21, the first semiconductor layer 201 having a large Al composition X and a large difference in lattice constant with respect to the silicon substrate 10 is arranged to a side closer to the silicon substrate 10. Thus, cracks and deterioration of film quality caused by a difference in lattice constant are restrained from happening in the light-emitting function layer 30.

According to the study by the inventors, in the multilayer film 21 including two to four lamination pairs, it is only necessary that a difference in Al composition of at least one lamination pair 200 is 0.5 or larger but not exceeding 0.8. In short, in the case where the first semiconductor layer 201 is an AlGaN film and the second semiconductor layer 202 is a GaN film, an Al composition X of at least one first semiconductor layer 201 in the multilayer film 21 is 0.5 or larger but not exceeding 0.8. According to the study by the inventors, it was found that, in a case where, for example, three lamination pairs 200 are included in the multilayer film 21, the buffer layer effect is obtained when a difference in Al composition is 0.5 or larger in two pairs out of the three pairs.

However, when the Al composition of the entire semiconductor DBR layer 20 is increased, cracks are more likely to occur. Therefore, in the lamination pair 200 with a difference in Al composition of 0.5 or larger, a difference in Al composition of 0.5 or larger but not exceeding 0.8 is preferred. In the case of three pairs, in order to restrain occurrence of cracks, it is preferred that a difference in Al composition in the lamination pairs 200, other than the lamination pair 200 with a difference in Al composition of 0.5 or larger, is 0.5 or smaller, or, more preferably, 0.2 or smaller. It is possible that a difference in Al composition in the lamination pair 200 with a small difference in Al composition is reduced to zero. However, when a difference in Al composition becomes zero, reflectance is reduced.

In the example shown in FIG. 2, the Al composition of the first semiconductor layer 201 of the first lamination pair 210 is 0.5 or larger but not exceeding 0.8, the Al composition of the first semiconductor layer 201 of the third lamination pair 230 is 0 or larger but not exceeding 0.2, and the Al composition of the first semiconductor layer 201 of the second lamination pair 220 is equal to or smaller than the Al composition of the first semiconductor layer 201 of the first lamination pair 210 and larger than the Al composition of the first semiconductor layer 201 of the third lamination pair 230. For example, as shown in FIG. 6, the first lamination pair 210 and the second lamination pair 220 are structured by the first semiconductor layers 201 made of Al_{0.6}GaN, and the second semiconductor layers 202 made of GaN, and the third lamination pair 230 is structured by the first semiconductor layer 201 made of Al_{0.2}GaN and the second semiconductor layer 202 made of GaN. The Al composition X of the first semiconductor layer of the third lamination pair 230 may be zero, and the first semiconductor layer 201 and the second semiconductor layer 202 of the third lamination pair 230 may both be GaN films. The reason is stated below. When, in particular, a size of a wafer is large such as 4 inches or larger, internal strain increases due to a difference in lattice constant between the silicon substrate 10 and the semiconductor DBR layer 20. An average Al composition is larger in the lamination pair 200 on a side closer to the silicon substrate 10, and tendency of occurrence of cracks becomes high due to a large difference in lattice constant. In such a case, by making both the first semiconductor layer 201 and the second semiconductor layer 202 into GaN films in a part of the lamination pairs 200 as stated above, internal strain is reduced, thereby suppressing occurrence of cracks more stably.

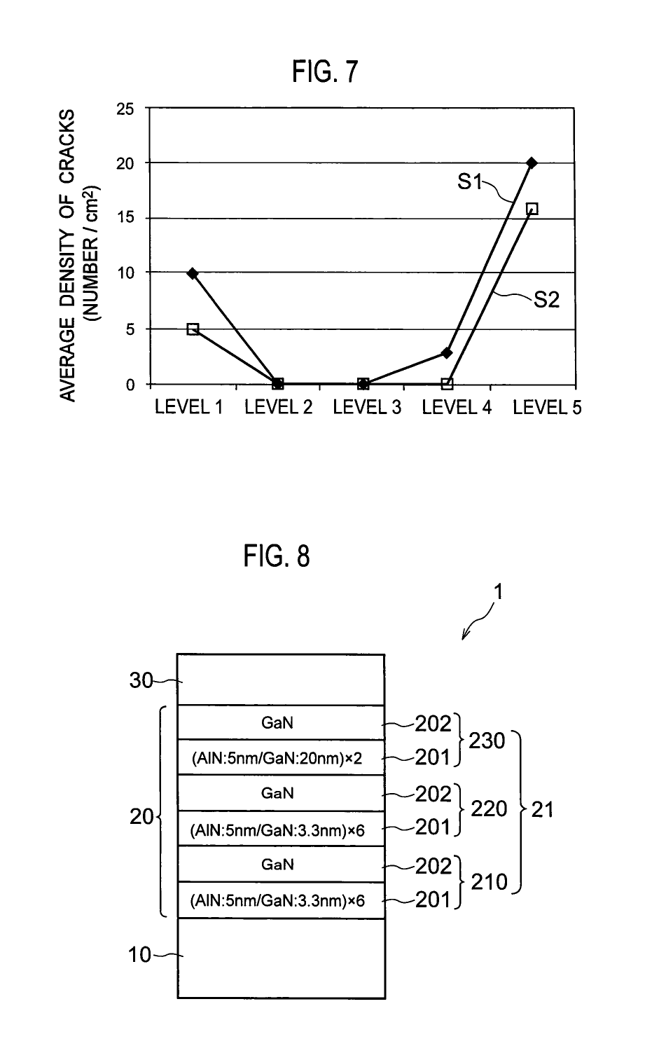

It is preferred that the first semiconductor layer 201 has a lamination structure made of an AlN film or an AlGaN film, and a GaN film, or a lamination structure made of an AlN film and an AlGaN film, and a GaN film, instead of a single AlGaN film. FIG. 7 shows a result of an investigation on occurrence of cracks in level 1 to level 5 in a case where the first semiconductor layer 201 is a single AlGaN film, and in a case where the first semiconductor layer 201 is made by laminating a laminated body made of an AlGaN film and a GaN film. A film thickness of any of the first semiconductor layers 201 is 50 nm. An average Al composition of the first semiconductor layers 201 in the case of the lamination structure is an average value of Al compositions of all the first semiconductor layers 201.

As shown in FIG. 7, a result was obtained that occurrence of cracks is suppressed more in the first semiconductor layer 201 with the lamination structure than the single layer. This is because the buffer layer effect is increased due to an increase in the number of heterojunctions within the first semiconductor layer 201. In the first semiconductor layer 201, similar results were obtained when the AlGaN films and the GaN films are laminated for five to nine times.

For example, as shown in FIG. 8, each of the first semiconductor layers 201 of the first lamination pair 210 and the second lamination pair 220 has a structure in which six laminated structures are laminated, each of which includes an AlN film with a film thickness of 5 nm and a GaN film with a film thickness of 3.3 nm. The first semiconductor layer 201 of the third lamination pair 230 has a structure in which two laminated structures are laminated, each of which includes an AlN film with a film thickness of 5 nm and a GaN film with a film thickness of 20 nm. The entire film thickness of the first semiconductor layer 201 is 50 nm. The second semiconductor layer 202 is a GaN film with a film thickness of 50 nm. In the case where the first semiconductor layer 201 has a laminated structure, an epitaxial layer of good quality without cracks is formed as long as there is a region in which a difference in Al composition between layers is 0.5 or larger in a film thickness range from 200 nm to 400 nm.

As explained so far, with the semiconductor device 1 according to the first embodiment of the present invention, the multilayer film 21, in which two to four lamination pairs 200 are laminated by combining the lamination pair 200 with a large difference in Al composition and the lamination pair 200 with a small difference in Al composition, is used for the semiconductor DBR layer 20. Thus, occurrence of cracks is restrained while obtaining the buffer layer effect. Therefore, it is not necessary to form a buffer layer between the silicon substrate 10 and the semiconductor DBR layer 20. Hence, an increase in manufacturing time is restrained, and productivity is improved. As a result, it is possible to restrain an increase in manufacturing costs for the semiconductor device 1 in which the semiconductor DBR layer 20 is arranged on the silicon substrate 10.

### Second Embodiment

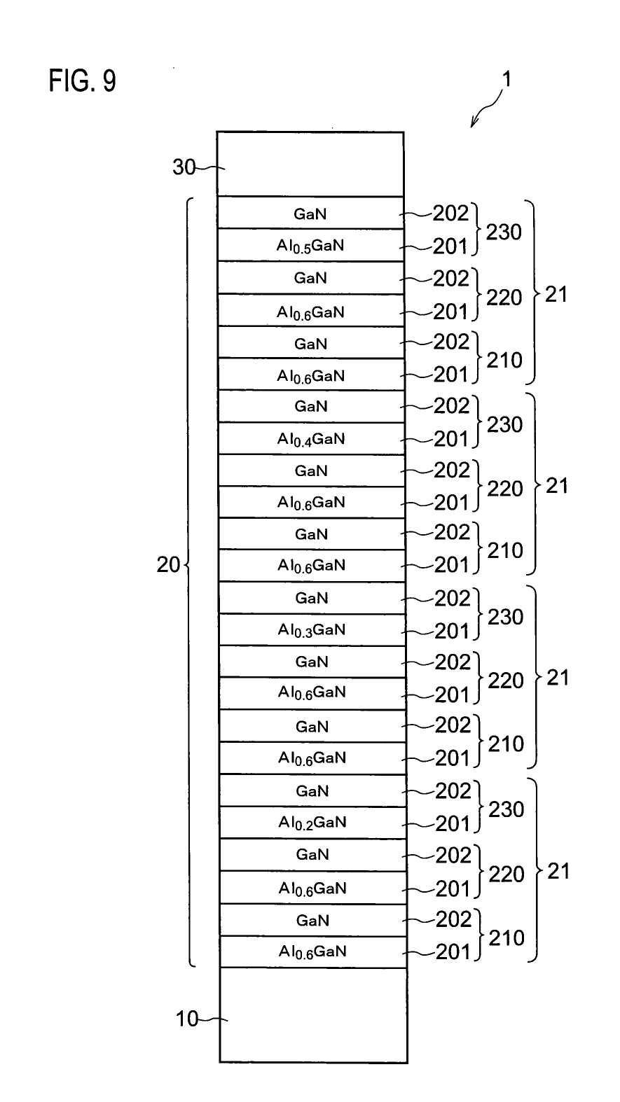

As shown in FIG. 9, a semiconductor device 1 according to a second embodiment of the present invention is different from FIG. 1 in that a semiconductor DBR layer 20 has a structure in which a plurality of multilayer films 21 are laminated. The rest of the structure is similar to that of the first embodiment shown in FIG. 1.

In the example shown in FIG. 9, the semiconductor DBR layer 20 is structured by laminating four multilayer films 21, each of which has three lamination pairs 200. Each of the multilayer films 21 has a structure in which first semiconductor layers 201 made of AlGaN, and second semiconductor layers 202 made of GaN are laminated. As shown in FIG. 9, in each of the multilayer films 21, an Al composition X of the first semiconductor layer 201 of the lamination pair 200 that is the closest to a light-emitting function layer 30 becomes larger as the multilayer film 21 becomes closer to the light-emitting function layer 30. In other words, an average Al composition of each of the multilayer films 21 is set to be gradually smaller in such multilayer film 21 as same is closer to the silicon substrate 10, and to be gradually larger the farther away from the silicon substrate 10. The reason is as follows.

As more multilayer films 21 are laminated, the buffer layer effect becomes greater, and crystal quality of the semiconductor DBR layer 20 is gradually improved towards the light-emitting function layer 30. This means that cracks are unlikely to happen. Therefore, even if an Al composition X is increased in the multilayer film 21 on a side away from the silicon substrate 10, a good epitaxial layer is obtained, in which occurrence of cracks is suppressed. An increase in the Al composition X is preferred because a difference in reflective index in the semiconductor DBR layer 20 becomes large, thereby improving reflectance.

By structuring the semiconductor DBR layer 20 by laminating the multilayer films 21, the number of heterojunctions is increased, thereby enhancing the buffer layer effect. Thus, occurrence of cracks is restrained further. The rest is substantially the same as the first embodiment, and duplicated description is omitted.

### Other Embodiments

In the previously-mentioned embodiments, the example was explained in which the film thicknesses of the first semiconductor layer 201 and the second semiconductor layer 202 are 50 nm. However, the film thicknesses of the first semiconductor layer 201 and the second semiconductor layer 202 are selected as appropriate in accordance with a wavelength of light emitted from the light-emitting function layer 30.

Various modifications will become possible for those skilled in the art after receiving the teachings of the present disclosure without departing from the scope thereof.

What is claimed is:

1. A semiconductor device comprising:
a silicon substrate;
a light-emitting function layer made of nitride semiconductor; and
at least one multilayer film in which two to four lamination pairs are laminated, the lamination pair being a laminated body of a first semiconductor layer made of AlₓGa₁₋ₓN (0≦X≦1) and a second semiconductor layer made of Al_{Y}Ga_{1-Y}N (0≦Y<1), the multilayer film being arranged between the silicon substrate and the light-emitting function layer, wherein,
in the lamination pair that is the closest to the light-emitting function layer in the multilayer film, an Al composition X of the first semiconductor layer is equal to or larger than an Al composition Y of the second semiconductor layer,
in the lamination pair other than the lamination pair that is the closest to the light-emitting function layer in the multilayer film, the Al composition X of the first semiconductor layer is larger than the Al composition Y of the second semiconductor layer,
in the multilayer film, the Al composition X of the first semiconductor layer of the lamination pair that is the closest to the silicon substrate is the largest among those of all the first semiconductor layers and the second semiconductor layers included in the multilayer film, and,
in the multilayer film, the Al composition X of the first semiconductor layer of the lamination pair that is the closes to the light-emitting function layer is the smallest among those of all the first semiconductor layers included in the multilayer film.

2. The semiconductor device of claim 1, wherein,
in the multilayer film, the Al composition X becomes gradually smaller from the first semiconductor layer that is the closest to the silicon substrate towards the first semiconductor layer that is the closest to the light-emitting function layer.

3. The semiconductor device of claim 1, wherein
a film thickness d₁ of the first semiconductor layer and a film thickness d₂ of the second semiconductor layer satisfy a relationship of
d_{1,2}=(α×λ)/(4×n_{1,2}) and 0.8≦α≦1.2
in which λ is a wavelength of light emitted from the light-emitting function layer, and n₁ and n₂ are reflective indexes of the first semiconductor layer and the second semiconductor layer.

4. The semiconductor device of claim 3, wherein,
in the multilayer film, a difference in Al composition between the first semiconductor layer and the second semiconductor layer in at least one of the lamination pairs is 0.5 or larger but not exceeding 0.8.

5. The semiconductor device of claim 4, wherein,
in the multilayer film that includes the lamination pair with the difference in Al composition of 0.5 or larger but not exceeding 0.8, the difference in Al composition in the other lamination pair is smaller than 0.5.

6. The semiconductor device of claim 1, wherein
the first semiconductor layer has a laminated structure of an AlN layer and a GaN layer.

7. The semiconductor device of claim 6, wherein
the first semiconductor layer is structured by laminating five to nine of the laminated structures.

8. The semiconductor device of claim 1, wherein
the multilayer film is made of a first lamination pair that is the closest to the silicon substrate, a second lamination pair arranged on the first lamination pair, and a third lamination pair arranged on the second lamination pair, and
a relation of
X1≧X2>X3
is satisfied, in which X1 is the Al composition of the first semiconductor layer in the first lamination pair, X2 is the Al composition of the first semiconductor layer in the second lamination pair, and X3 is the Al composition of the first semiconductor layer in the third lamination pair.

9. The semiconductor device of claim 8, wherein
the Al composition of the first semiconductor layer in the third lamination pair is zero.

10. The semiconductor device of claim 1, wherein
a plurality of the multilayer films are laminated, and
an average Al composition of each of the multilayer films becomes smaller in such multilayer film as same is closer to the silicon substrate, and becomes larger the farther away from the silicon substrate.

11. The semiconductor device of claim 1, wherein two or more of the multilayer films are formed between the silicon substrate and the light-emitting function layer.

12. The semiconductor device of claim 10, wherein the Al composition X of the first semiconductor layer of the lamination pair that is the closest to the light-emitting function layer in each of the multilayer films becomes larger, the farther away from the silicon substrate.
